(19) United States
(12) Patent Application Publication
(10) Pub. No.: US 2026/0006914 A1
(43) Pub. Date: Jan. 1, 2026

(54) DISPLAY SUBSTRATE, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Hongda SUN, Beijing (CN); Fengjuan LIU, Beijing (CN); Hehe HU, Beijing (CN); Guangcai YUAN, Beijing (CN); Ce NING, Beijing (CN); Dongfang WANG, Beijing (CN)

(21) Appl. No.: 18/881,270

(22) PCT Filed: May 24, 2024
(86) PCT No.: PCT/CN2024/095255

§ 371 Date: Jan. 4, 2025

(30) Foreign Application Priority Data
May 26, 2023 (CN) 202310611117.2

(51) Int. Cl. H10D 86/40; H10D 86/60

(52) U.S. Cl. CPC H10D 86/441; H10D 86/60

(57) ABSTRACT

A display substrate, display panel, and display device. The display substrate comprises an active layer, a first insulating layer, a first metal layer, a second insulating layer, and a first conductive electrode sequentially arranged on a base; the first metal layer comprises a gate and a first electrode; the portion, exposed through a first via hole formed in the first insulating layer, of the active layer comprises first and second sub-portions; the first electrode is in lap joint with the first sub-portion by the first via hole; a second via hole is formed in the second insulating layer and located on the side, distant from the gate, of a partition boundary of the first and second sub-portions; orthographic projections of the second via hole and the first electrode on the base partially overlap; and the first conductive electrode is connected to the first electrode by the second via hole.

### CROSS-REFERENCE TO RELATED APPLICATIONS

The present application is a U.S. National Phase Entry of International Application No. PCT/CN2024/095255 having an international filing date of May 24, 2024, which claims priority to Chinese Patent Application No. 202310611117.2, filed to the CNIPA on May 26, 2023, which are incorporated herein by reference in their entireties.

### TECHNICAL FIELD

Embodiments of the present disclosure relate to, but are not limited to, the field of display technologies, and in particular, relate to a display substrate, a display panel and a display device.

### BACKGROUND

Thin film transistors made of amorphous silicon (a-Si) are usually used in display substrates. With the development of technology, thin film transistors made of oxide semiconductors have been used in display substrates. Oxide semiconductor technology can improve performance and reduce cost, which is beneficial for launching low-cost display products.

### SUMMARY

The following is a summary of subject matter described in the present disclosure in detail. This summary is not intended to limit the protection scope of claims.

As a first aspect of the embodiments of the present disclosure, an embodiment of the present disclosure provides a display substrate, including:
a base;
an active layer located on a side of the base;
a first insulating layer located on a side of the active layer away from the base, wherein the first insulating layer is provided with a first via hole that exposes a portion of a surface of the active layer;
a first metal layer located on a side of the first insulating layer away from the base, wherein the first metal layer includes a gate and a first electrode, a portion of the active layer exposed through the first via hole includes a first sub-portion and a second sub-portion, the first sub-portion is located on a side of the second sub-portion away from the gate, and the first electrode is connected with the first sub-portion in a lapping mode through the first via hole;
a second insulating layer located on a side of the first metal layer away from the base, wherein the second insulating layer is provided with a second via hole, an orthographic projection of the second via hole on the base is at least partially overlapped with an orthographic projection of the first electrode on the base, the orthographic projection of the second via hole on the base is located on a side of a first boundary away from the gate, and the first boundary is a partition boundary between the first sub-portion and the second sub-portion; and
a first conductive electrode located on a side of the second insulating layer away from the base, wherein the first conductive electrode is connected with the first electrode through the second via hole.

In some embodiments, the orthographic projection of the second via hole on the base is located in the orthographic projection of the first electrode on the base.

In some embodiments, the display substrate further includes an auxiliary barrier layer disposed in a same layer as the active layer, wherein the orthographic projection of the second via hole on the base is partially overlapped with the orthographic projection portion of the first electrode on the base, and an orthographic projection of a portion of the second via hole outside the first electrode on the base is within an orthographic projection of the auxiliary barrier layer on the base.

In some embodiments, the display substrate further includes a planarization layer disposed between the second insulating layer and the first conductive electrode, wherein the planarization layer is provided with a third via hole, the orthographic projection of the second via hole on the base is at least partially overlapped with an orthographic projection of the third via hole on the base, and the second via hole penetrates the planarization layer and the second insulating layer.

In some embodiments, a second boundary is located on a side of the first boundary b1 close to the gate, and the second boundary is a boundary on a side of the third via hole close to the gate.

In some embodiments, the orthographic projection of the second via hole on the base is within a range of the orthographic projection of the third via hole on the base, and a distance between a boundary of the orthographic projection of the second via hole on the base and a boundary of the orthographic projection of the third via hole on the base is greater than or equal to 2 μm.

In some embodiments, the orthographic projection of the second via hole on the base is located within a range of the orthographic projection of the third via hole on the base, a distance between the second boundary and a fourth boundary is larger than a distance between a third boundary and a fifth boundary, the fourth boundary is a boundary on a side of the second via hole close to the gate, the third boundary is a boundary on a side of the third via hole away from the gate, and the fifth boundary is a boundary on a side of the second via hole away from the gate.

In some embodiments, a second boundary is located on a side of the first boundary away from the gate, the second boundary is a boundary on a side of the third via hole close to the gate, and the orthographic projection of the second via hole on the base is located on a side of the second boundary away from the gate.

In some embodiments, there is a first overlapping region between the orthographic projection of the second via hole on the base and the orthographic projection of the third via hole on the base, a ratio of an area of the first overlapping region to an area of the orthographic projection of the third via hole on the base ranges from 0.1 to 0.8, and a ratio of the area of the first overlapping region to an area of the orthographic projection of the second via hole on the base ranges from 0.5 to 1.

In some embodiments, the display substrate further includes a second metal layer and a buffer layer between the base and the active layer, wherein the second metal layer is close to the base, the second metal layer includes a data line, the first metal layer further includes a gate line and a second electrode, the first electrode and the second electrode respectively located on two sides of the gate, the first insulating layer is further provided with a fourth via hole, the second electrode is connected to the active layer and the data line through the fourth via hole, the first electrode is provided with a first notch, and the first notch is located at a position of the first electrode adjacent to the data line and the gate line.

In some embodiments, the first notch includes a sixth boundary and a seventh boundary, the sixth boundary is parallel to the gate line, a distance between the sixth boundary and the gate line is greater than or equal to 2.5 μm, the seventh boundary is parallel to the data line, and a distance between the seventh boundary and the data line is greater than or equal to 2.5 μm.

In some embodiments, the first metal layer further includes a gate line, a boundary of the first electrode close to the gate line is parallel to the gate line, a boundary of the active layer close to the gate line is parallel to the gate line, a distance between the first electrode and the gate line is greater than a distance between the active layer and the gate line, a distance between the first electrode and the gate line is greater than or equal to 2.5 μm, and an orthographic projection of a boundary of the third via hole close to the gate line on the base is between the orthographic projection of the first electrode on the base and an orthographic projection of the gate line on the base.

In some embodiments, the active layer is provided with a second notch located at a position of the active layer adjacent to the data line and the gate line, the second notch includes an eighth boundary, the eighth boundary is parallel to the gate line, and an orthographic projection of the eighth boundary on the base is located at an inner side of the orthographic projection of the first electrode on the base.

In some embodiments, the orthographic projection of the second via hole on the base is within the orthographic projection of the first electrode on the base, and the orthographic projection of the second via hole on the base is partially overlapped with the orthographic projection of the third via hole on the base.

In some embodiments, the boundary of the third via hole close to the gate line is located between the orthographic projection of the first electrode on the base and the orthographic projection of the gate line on the base, and the orthographic projection of the second via hole on the base is located within the orthographic projection of the third via hole on the base.

In some embodiments, the display substrate further includes a second metal layer and a buffer layer between the base and the active layer, wherein the second metal layer is close to the base, the second metal layer includes a data line and a shield portion, the first metal layer further includes a second electrode, the first electrode and the second electrode is respectively located on two sides of the gate, the first insulating layer is further provided with a fourth via hole, the second electrode is connected to the active layer and the data line through the fourth via hole, and an orthographic projection of the gate on the base is located within an orthographic projection of the shield portion on the base.

In some embodiments, the display substrate further includes a second metal layer and a buffer layer between the base and the active layer, wherein the second metal layer is close to the base, the second metal layer includes an adapter portion, and the first electrode is further connected to the adapter portion through the first via hole.

As a second aspect of an embodiment of the present disclosure, an embodiment of the present disclosure provides a display panel, including the display substrate according to any one of the embodiments of the present disclosure.

As a third aspect of the embodiments of the present disclosure, an embodiment of the present disclosure provides a display device, including the display substrate or the display panel according to any one of the embodiments of the present disclosure.

The above summary is for the purpose of the description only and is not intended to limit in any manner. Further aspects, embodiments and features of the present disclosure will be readily understood by referring to the accompanying drawings and the detailed description below in addition to the illustrative aspects, embodiments and features described above.

Other aspects of the present disclosure may be comprehended after the drawings and the detailed descriptions are read and understood.

### BRIEF DESCRIPTION OF DRAWINGS

In the accompanying drawings, unless otherwise specified, same reference numerals throughout a plurality of drawings indicate same or similar components or elements. These drawings may not be drawn in scale. It should be understood that these drawings depict only some implementations according to the present disclosure and should not be considered as limiting the scope of the present disclosure.

FIG. 1 shows a schematic cross-sectional view of a display substrate.

FIG. 2A shows a test graph of a thin film transistor before annealing of the display substrate shown in FIG. 1.

FIG. 2B shows a test graph of a thin film transistor after annealing of the display substrate shown in FIG. 1.

FIG. 3 shows a schematic cross-sectional view of a display substrate according to an embodiment of the present disclosure.

FIG. 4 shows a schematic planar view of a part of a display substrate according to an embodiment of the present disclosure.

FIG. 5 shows a schematic cross-sectional view of a display substrate according to another embodiment of the present disclosure.

FIG. 6 shows a schematic planar view of a part of a display substrate according to another embodiment of the present disclosure.

FIG. 7 shows a schematic diagram of a shape of a via hole.

FIG. 8 shows a schematic cross-sectional view of a display substrate according to another embodiment of the present disclosure.

FIG. 9 shows a schematic planar view of a part of a display substrate according to another embodiment of the present disclosure.

FIG. 10 shows a schematic planar view of a part of a display substrate according to another embodiment of the present disclosure.

FIG. 11 shows a schematic planar view of a part of a display substrate according to another embodiment of the present disclosure.

FIG. 12 shows a schematic planar view of a part of a display substrate according to another embodiment of the present disclosure.

FIG. 13 shows a schematic cross-sectional view of a display substrate according to another embodiment of the present disclosure.

FIG. 14 shows a schematic planar view of a part of a display substrate according to another embodiment of the present disclosure.

FIG. 15 shows a schematic cross-sectional view of a display substrate according to another embodiment of the present disclosure.

FIG. 16 shows a schematic planar view of a part of a display substrate according to another embodiment of the present disclosure.

FIG. 17 shows a schematic cross-sectional view of a display substrate according to another embodiment of the present disclosure.

FIG. 18 shows a schematic planar view of a part of a display substrate according to another embodiment of the present disclosure.

FIG. 19 shows a schematic planar view of a display substrate according to another embodiment of the present disclosure.

FIG. 20A shows a schematic cross-sectional view of a display substrate after a first insulating layer is formed therein according to an embodiment of the present disclosure.

FIG. 20B shows a schematic cross-sectional view of a display substrate after a first metal layer is formed therein according to an embodiment of the present disclosure.

FIG. 20C shows a schematic cross-sectional view of a display substrate after an active layer is conducted therein according to an embodiment of the present disclosure.

### DETAILED DESCRIPTION

Implementations of the present disclosure will be described further in detail below with reference to the accompanying drawings and embodiments. The following embodiments are intended to illustrate the present disclosure and are exemplary only, but are not intended to limit the scope of the present disclosure.

Hereinafter, only some exemplary embodiments are briefly described. As will be recognized by those skilled in the art, the described embodiments may be modified in a variety of different ways without departing from the essence or scope of the present disclosure, and the different embodiments may be arbitrarily combined if there is no conflict. Therefore, the drawings and description are considered to be exemplary in nature and not restrictive.

In the related art, in a display substrate using an oxide semiconductor, there is a problem of insufficient charging of pixel electrodes, which reduces the performance of the display substrate.

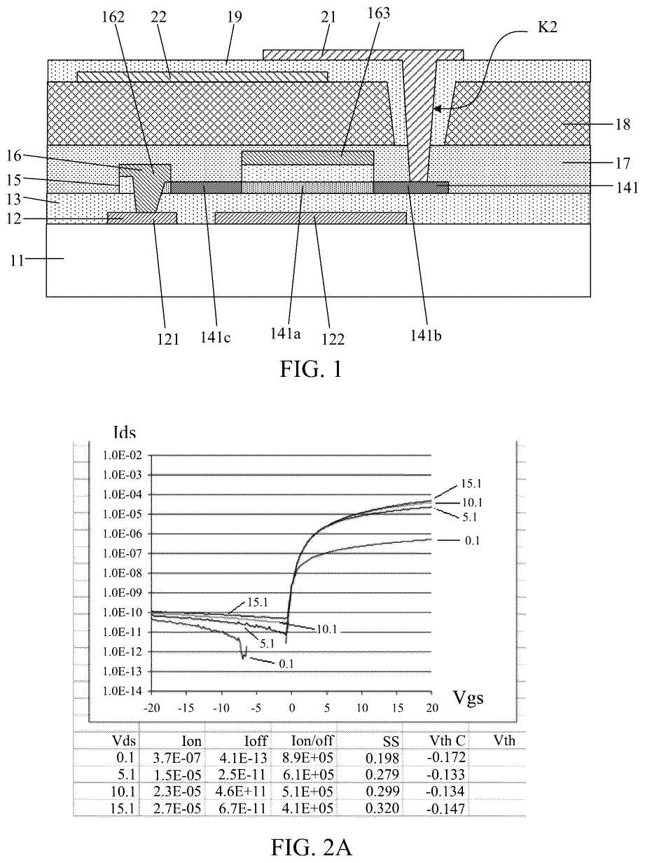

FIG. 1 shows a schematic cross-sectional view of a display substrate. As shown in FIG. 1, the display substrate may include a base 11, an active layer 141 disposed on an upper side of the base 11, a first insulating layer 15 disposed on a side of the active layer 141 away from the base 11, and a first metal layer 16 disposed on a side of the first insulating layer 15 away from the base 11. The first metal layer 16 includes a gate 163 and a source, and the active layer 141 includes a channel region 141a, and a first conductive region 141b and a second conductive region 141c located on two sides of the channel region 141a. Exemplarily, the active layer 141 may be conducted after the first metal layer 16 is formed, to form the first conductive region 141b and the second conductive region 141c. The source is connected with the second conductive region 141c. The display substrate further includes a second insulating layer 17, a planarization layer 18, and a third insulating layer 19 sequentially disposed on the first metal layer 16. A first conductive electrode 21 is located on the third insulating layer 19, and the first conductive electrode 21 is connected with the first conductive region 141b through a second via hole K2 penetrating the third insulating layer 19, the planarization layer 18, and the second insulating layer 17.

As shown in FIG. 1, the display substrate may further include a second conductive electrode 22 located between the planarization layer 18 and the third insulating layer 19. Exemplarily, the first conductive electrode 21 may be a pixel electrode, and the second conductive electrode 22 may be a common electrode.

As shown in FIG. 1, the display substrate may further include a second metal layer 12 and a buffer layer 13, the second metal layer 12 may include a data line 121 and a shield portion 122, and the source of the first metal layer 16 is connected with the data line 121 through a via hole penetrating the first insulating layer 15.

The first conductive electrode 21 is usually made of a transparent conductive material, but the transparent conductive material has poor coverage and density, resulting in that the second via hole K2 is exposed to air in a process after the first conductive electrode 21 is formed. Through experiments, it has been proved that after a subsequent temperature process such as annealing of the display substrate, anti-conduction occurs in a conductive region where the second via hole K2 is located, resulting in an increase of a connection resistance between the first conductive electrode 21 and the first conductive region 141b, thereby causing insufficient charging of the pixel electrode, and the deteriorative performance of the display substrate.

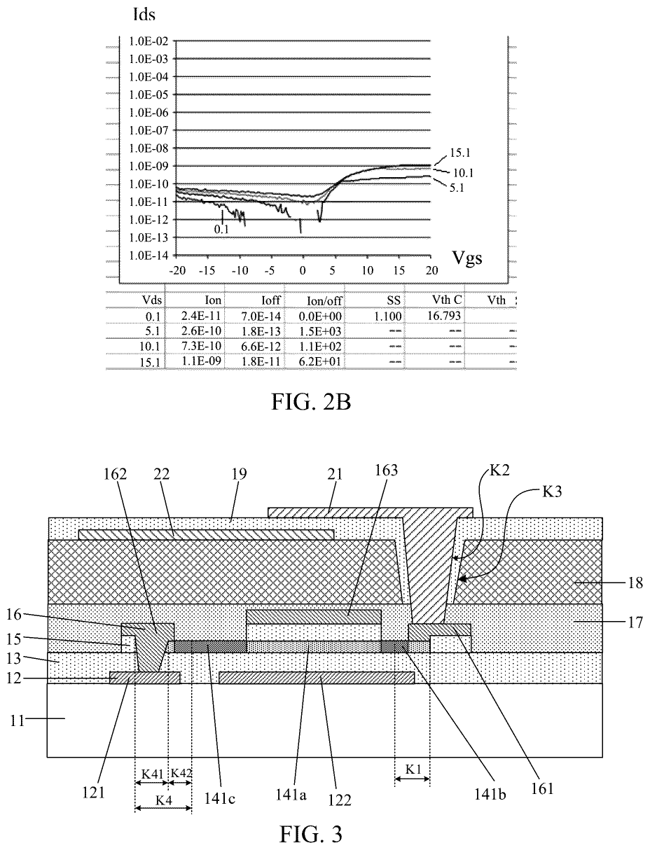

FIG. 2A shows a test graph of a thin film transistor before annealing of the display substrate shown in FIG. 1; and FIG. 2B shows a test graph of a thin film transistor after annealing of the display substrate shown in FIG. 1. Exemplarily, a lapping resistance between the first conductive electrode 21 and the conductive region may be tested by detecting the thin film transistor. By comparing FIGS. 2A and 2B, it can be seen that under the same Vds and Vgs, an Ids of the thin film transistor before annealing is much larger than an Ids of the thin film transistor after annealing, and thus, it can be seen that a lapping resistance between the first conductive electrode 21 and the first conductive region 141b after annealing is much larger than a lapping resistance between the first conductive electrode 21 and the first conductive region 141b before annealing.

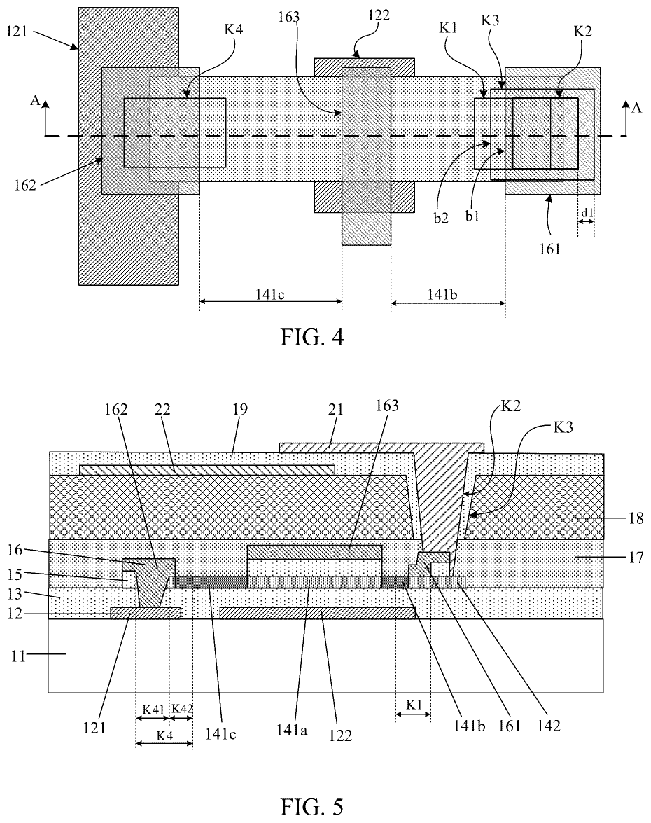

FIG. 3 shows a schematic cross-sectional view of a display substrate according to an embodiment of the present disclosure, FIG. 4 shows a schematic planar view of a part of a display substrate according to an embodiment of the present disclosure, and FIG. 3 shows a schematic cross-sectional view taken along line A-A of the display substrate shown in FIG. 4. As shown in FIGS. 3 and 4, the display substrate may include a base 11, an active layer 141, a first insulating layer 15, a first metal layer 16, a second insulating layer 17, and a first conductive electrode 21.

The active layer 141 may be located on one side of the base 11, and the first insulating layer 15 may be located on a side of the active layer 141 away from the base 11, and the first insulating layer 15 is provided with a first via hole K1 that exposes a portion of a surface of the active layer 141.

The first metal layer 16 is located on a side of the first insulating layer 15 away from the base 11, and the first metal layer 16 includes a gate 163 and a first electrode 161. The portion of the active layer 141 exposed through the first via hole K1 includes a first sub-portion and a second sub-portion, the second sub-portion is close to the gate 163, and the first sub-portion is located on a side of the second sub-portion away from the gate 163. The first electrode 161 is connected with the first sub-portion in a lapping mode through the first via hole K1.

Herein, “the portion of the active layer 141 exposed through the first via hole K1” may mean that “the portion of the active layer 141 exposed through the first via hole K1” is exposed before the first via hole K1 is formed and other film layers are not formed on the first insulating layer 15, and “the portion of the active layer 141 exposed through the first via hole K1” may be covered by a subsequent film layer. “The portion of the active layer 141 exposed through the first via hole K1” may refer to a portion where the active layer 141 is overlapped with the first via hole K1, or a portion of the active layer 141 located in a region where the first via hole K1 is located.

The second insulating layer 17 is located on a side of the first metal layer 16 away from the base 11. The second insulating layer 17 is provided with a second via hole K2. An orthographic projection of the second via hole K2 on the base 11 is at least partially overlapped with an orthographic projection of the first electrode 161 on the base 11. The orthographic projection of the second via hole K2 on the base 11 is located on a side of a first boundary b1 away from the gate 163, and the first boundary bl is a partition boundary between the first sub-portion and the second sub-portion. The first conductive electrode 21 is located on a side of the second insulating layer 17 away from the base 11, and the first conductive electrode 21 is connected with the first electrode 161 through the second via hole K2.

In an exemplary example, as shown in FIGS. 3 and 4, the first metal layer 16 may further include a second electrode 162, and the thin film transistor may include the first electrode 161, the second electrode 162, the gate 163, and the active layer 141. Exemplarily, the first electrode 161 may be a drain, and the second electrode 162 may be a source. The active layer 141 may include a channel region 141a, and a first conductive region 141b and a second conductive region 141c located on two sides of the channel region 141a. Exemplarily, after the first metal layer 16 is formed, the active layer 141 may be conducted, and a portion of the active layer 141 located under the gate 163 forms the channel region 141a. A portion of the active layer 141 located between the gate 163 and the second electrode 162 forms the second conductive region 141c, and the second electrode 162 is connected with the second conductive region 141c. A portion of the active layer 141 located between the gate 163 and the first electrode 161 forms the first conductive region 141b, and the first electrode 161 is connected with the first conductive region 141b. The first conductive region 141b includes a second sub-portion.

In an embodiment of the present disclosure, as shown in FIG. 3, the portion of the active layer 141 exposed through the first via hole K1 includes a first sub-portion and a second sub-portion, wherein the second sub-portion is close to the gate 163, the first sub-portion is located on a side of the second sub-portion away from the gate 163, and the first electrode 161 is connected with the first sub-portion in a lapping mode through the first via hole K1. In such a structure, when a conductive processing is performed on the exposed surface of the active layer 141, it is also performed on the first sub-portion along the first boundary b1, so that at least a portion of the first sub-portion covered by the first electrode 161 is conducted, thereby the first electrode 161 can be electrically connected with the active layer 141 through the conducted portion of the first sub-portion, and a connection resistance between the first electrode 161 and the active layer 141 is reduced.

Compared to the display substrate shown in FIG. 1, in the display substrate of the embodiment of the present disclosure, the orthographic projection of the second via hole K2 on the base 11 is located on a side of the first boundary bl away from the gate 163, and the first boundary b1 is the partition boundary between the first sub-portion and the second sub-portion, so that the first conductive region 141b is not affected when the second via hole K2 is formed by an etching process, and a stability of the characteristics of the thin film transistor is ensured. The first electrode 161 is connected with the first sub-portion in a lapping mode through the first via hole K1, and the first conductive electrode 21 is connected with the first electrode 161 through the second via hole K2, thereby realizing a connection between the first conductive electrode 21 and the active layer 141.

The orthographic projection of the second via hole K2 on the base 11 is located on a side of the first boundary b1 away from the gate 163, that is, the orthographic projection of the second via hole K2 on the base 11 is located in a region outside the first conductive region 141b between the first electrode 161 and the gate 163. Therefore, the second via hole K 2 does not expose the first conductive region 141b of the active layer 141, and the first conductive region 141 b is covered by the second insulating layer 17. Therefore, in processes after the first conductive electrode 21 is formed, anti-conduction will not occur in the first conductive region 141b, the connection resistance between the first conductive electrode 21 and the active layer 141 is reduced, and a power consumption of the product is reduced. Therefore, compared to the display substrate in FIG. 1, in the display substrate according to the embodiment of the present disclosure the connection resistance between the first conductive electrode and the active layer is reduced, the charging current of the product is improved, and the performance of the display substrate is improved.

In one embodiment, as shown in FIG. 4, the orthographic projection of the second via hole K2 on the base 11 may be located within an orthographic projection of the first electrode 161 on the base 11. With such a structure, when the second via hole K2 is formed by etching, the first electrode 161 can serve as a shield layer for the second via hole K2 to avoid etching the active layer 141 or other film layers located under the first electrode 161, and a contact area between the first conductive electrode 21 and the first electrode 161 can be increased, and a contact resistance between the first conductive electrode 21 and the first electrode 161 can be reduced.

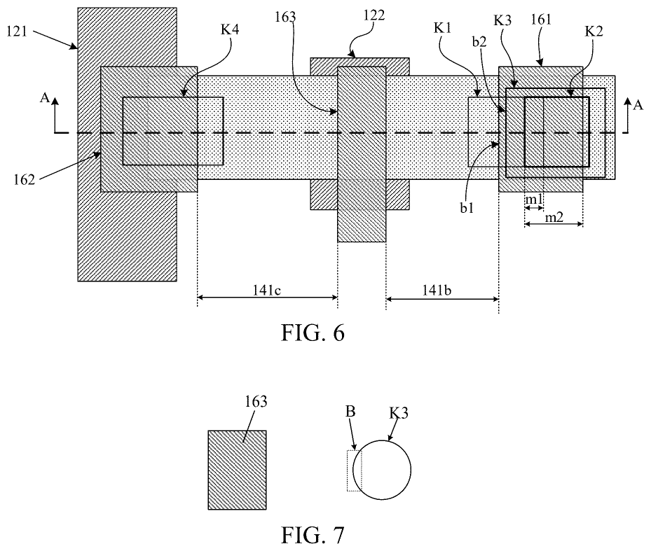

FIG. 5 shows a schematic cross-sectional view of a display substrate according to another embodiment of the present disclosure, FIG. 6 shows a schematic planar view of a part of a display substrate according to another embodiment of the present disclosure, and FIG. 5 shows a schematic cross-sectional view taken along A-A in the display substrate shown in FIG. 6. In one embodiment, the orthographic projection of the second via hole K2 on the base 11 may be partially overlapped with the orthographic projection of the first electrode 161 on the base 11. In this case, a portion of the second via hole K2 is located in a region where the first electrode 161 is located, and the other portion of the second via hole K2 is located in a region outside the first electrode 161, and when the second via hole K2 is formed by the etching process, film layers located under the active layer 141 may be etched. In order to avoid damage to other film layers by the etching process, the display substrate may further include an auxiliary barrier layer 142, the auxiliary barrier layer 142 may be disposed in a same layer as the active layer 141, and the auxiliary barrier layer 142 and the active layer 141 may be formed as an integral structure. An orthographic projection of the portion of the second via hole K2 located outside the first electrode 161 on the base 11 is located within an orthographic projection of the auxiliary barrier layer 142 on the base 11. Therefore, when the second via hole K2 is formed by the etching process, the first electrode 161 and the auxiliary barrier layer 142 can be jointly served as a barrier layer of the etching process to avoid etching other film layers under the active layer 141.

If the auxiliary barrier layer 142 is not disposed in the embodiment of FIGS. 5 and 6, the etching process for forming the second via hole K2 will etch the buffer layer 13 located under the active layer 141, and an overetching amount of the second via hole K2 is usually 10%, so that a pit having a depth of 400 Angstroms-to 1000 Angstroms may be formed on an upper surface of the buffer layer 13. It can be understood that the pit on the upper surface of the buffer layer 13 do not affect the performance of the thin film transistor.

As illustrated in FIG. 6, a distance m1 between a boundary on a side of the first via hole K1 away from the gate 163 and a boundary on a side of the second via hole K2 close to the gate 163 may be 0.5 μm to 4 μm. The distance m2 between a boundary on a side of the first electrode 161 away from the gate 163 and the boundary on the side of the second via hole K2 close to the gate 163 may be 1 μm to 6 μm. The boundary on the side of the second via hole K2 away from the gate 163 is located in a region outside the first electrode 161.

In one embodiment, as shown in FIGS. 3 to 6, the display substrate may further include a planarization layer 18 disposed between the second insulating layer 17 and the first conductive electrode 21, and the planarization layer 18 is provided with a third via hole K3. The orthographic projection of the second via hole K2 on the base is at least partially overlapped with an orthographic projection of the third via hole K3 on the base 11, and the second via hole K2 penetrates the planarization layer 18 and the second insulating layer 17. By disposing the planarization layer 18, the first conductive electrode 21 can be formed on a planarization surface, which is advantageous for improving the display effect.

As shown in FIGS. 3 and 5, the display substrate may further include a third insulating layer 19 located between the planarization layer 18 and the first conductive electrode 21. The second via hole K2 also penetrates the third insulating layer 19. Exemplarily, the third via hole K3 may be formed first, and after the third insulating layer 19 is deposited, the second via hole K2 penetrating the third insulating layer 19, the planarization layer 18, and the second insulating layer 17 may be formed by the etching process.

In one embodiment, as shown in FIGS. 3 to 6, the display substrate may further include a second metal layer 12 and a buffer layer 13 located between the base 11 and the active layer 141, and the second metal layer 12 is close to the base 11. That is, the second metal layer 12 is located on a side of the base 11, the buffer layer 13 is located on a side of the second metal layer 12 away from the base 11, and the active layer 141 is located on a side of the buffer layer 13 away from the base 11. The first metal layer 16 further includes a second electrode 162, and the first electrode 161 and the second electrode 162 are located on two sides of the gate 163, respectively. The second metal layer 12 includes a data line 121. The first insulating layer 15 is further provided with a fourth via hole K4, and the second electrode 162 is connected with the active layer 141 and the data line 121 through the fourth via hole K4.

Exemplarily, the fourth via hole K4 may include a third sub-hole K41 and a fourth sub-hole K42, wherein the third sub-hole K41 penetrates the first insulating layer 15 and the buffer layer 13 and exposes a portion of a surface of the data line 121, and the fourth sub-hole K42 penetrates the first insulating layer 15 and exposes a portion of a surface of the active layer 141. The second electrode 162 is connected with the data line 121 through the third sub-hole K41, and the second electrode 162 is connected with the portion of the surface of the active layer 141 exposed through the fourth sub-hole K42 in a lapping mode through the fourth sub-hole K42. In such a structure, when a conductive processing is performed on the active layer 141 after the first metal layer 16 is formed, it is also performed on the active layer 141 covered by the second electrode 162 along a lapping boundary between the second electrode 162 and the active layer 141, so that at least a portion of the active layer 141 covered by the second electrode 162 is conducted. Accordingly, the second electrode 162 can be electrically connected with the active layer 141 through a conducted portion located under the second electrode 162, thereby reducing the connection resistance between the second electrode 162 and the active layer 141, and further improving the performance of the thin film transistor.

In one embodiment, as shown in FIGS. 4, 6, 9 to 12, the second metal layer 12 may further include a shield portion 122, and an orthographic projection of the gate 163 on the base 11 is located within an orthographic projection of the shield portion 122 on the base 11. For example, the shield portion 122 may shield the channel region 141a of the active layer 141 to prevent external light from affecting the performance of the thin film transistor.

In one embodiment, as shown in FIGS. 4 and 6, shapes of via holes such as the first via hole K1, the second via hole K2, the third via hole K3, and the fourth via hole K4 in the display substrate are rectangular. In some other embodiments, a shape of a via hole may be any shape such as a circle, an ellipse, or a polygon, and the shape of the via hole is not limited herein, and the shape of the via hole may be disposed as necessary. For example, a boundary on a side of a via hole close to the gate 163 may be a portion of the boundary on the side of the via hole close to the gate 163. For example, in FIG. 4, a shape of the third via hole K3 is rectangular, and a boundary on a side of the third via hole K3 close to the gate 163 may be a left boundary of the third via hole K3; when the shape of the third via hole K3 is a curved shape, the boundary on the side of the third via hole K3 close to the gate 163 may refer to a portion of the boundary on the side of the third via hole K3 close to the gate 163. For example, in FIG. 7, the boundary on the side of the third via hole K3 close to the gate 163 is a boundary portion of the boundary of the third via hole K3 located within a B region. FIG. 7 shows a schematic diagram of a shape of a via hole.

Exemplarily, as shown in FIG. 4, a second boundary b2 may be a boundary on the side of the third via hole K3 close to the gate 163, and the second boundary b2 is located on a side of a first boundary b1 close to the gate 163. Exemplarily, the orthographic projection of the second via hole K2 on the base 11 is located within the orthographic projection of the third via hole K3 on the base 11, and the second boundary b2 is disposed to be located on the side of the first boundary b1 close to the gate 163, which can ensure that a size between the second via hole K2 and the gate 163 is minimized when the orthographic projection of the second via hole K2 on the base 11 is located on the side of the first boundary b1 away from the gate 163, thereby beneficial for reducing a size of the thin film transistor and improving an aperture ratio of the product.

As shown in FIG. 4, the orthographic projection of the second via hole K2 on the base 11 is within a range of the orthographic projection of the third via hole K3 on the base 11. A distance d1 between a boundary of the orthographic projection of the second via hole K2 on the base 11 and a boundary of the orthographic projection of the third via hole K3 on the base 11 is greater than or equal to 2 μm. Exemplarily, the second insulating layer 17 is deposited on the side of the first metal layer 16 away from the base 11; the planarization layer 18 is coated on the side of the second insulating layer 17 away from the base 11, and the third via hole K3 is formed after the planarization layer 18 is patterned; the third insulating layer 19 is deposited on the side of the planarization layer 18 away from the base 11, and the second via hole K2 is formed after the third insulating layer 19 and the second insulating layer 17 within the region of the third via hole K3 are patterned. By disposing the distance d1 between the boundary of the orthographic projection of the second via hole K2 on the base 11 and the boundary of the orthographic projection of the third via hole K3 on the base 11 to be greater than or equal to 2 μm, it can be ensured that only a material of the insulating layer is etched in a process of forming the second via hole K2 by the etching process, and a material of the planarization layer 18 is usually not to etched, thereby improving an etching rate and improving a production efficiency.

In an exemplary embodiment, in actual production, the etched second and third via holes are typically tapered via holes, i.e., bottom areas of the via holes are smaller than top areas thereof. In an embodiment of the present disclosure, the orthographic projection of the second via hole on the base may be an orthographic projection of a side of the second via hole close to the base on the base, and the orthographic projection of the third via hole on the base may be an orthographic projection of a side of the third via hole close to the base on the base. Actual sizes of the second via hole and the third via hole may be disposed as desired and are not limited herein.

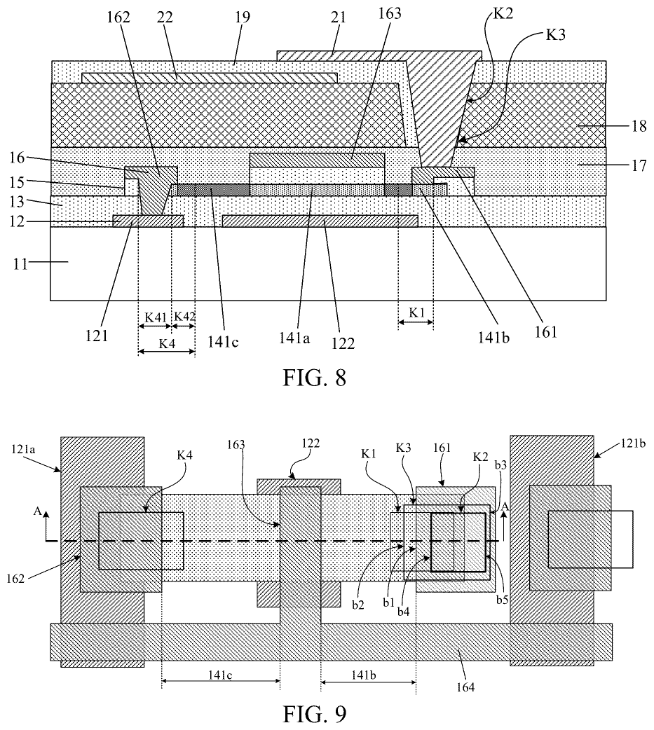

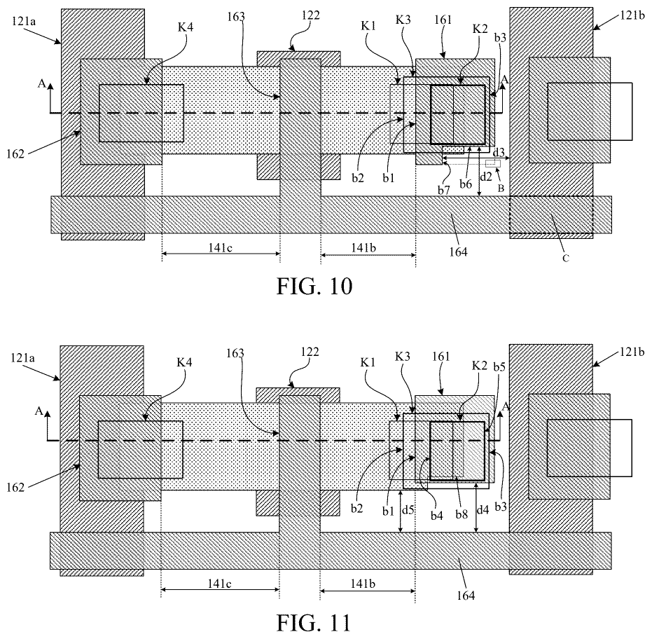

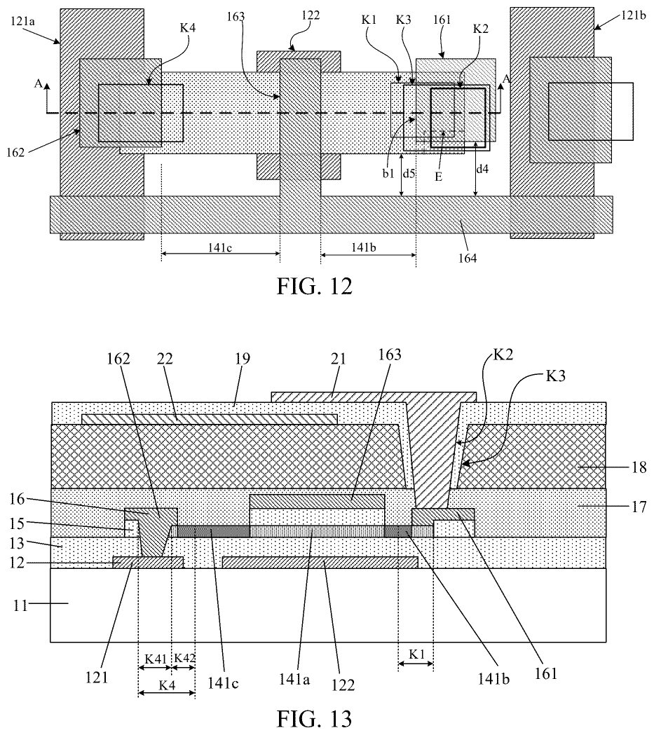

FIG. 8 shows a schematic cross-sectional view of a display substrate according to another embodiment of the present disclosure, FIG. 9 shows a schematic planar view of a part of a display substrate according to another embodiment of the present disclosure, FIG. 10 shows a schematic planar view of a part of a display substrate according to another embodiment of the present disclosure, FIG. 11 shows a schematic planar view of a part of a display substrate according to another embodiment of the present disclosure, FIG. 12 shows a schematic planar view of a part of a display substrate according to another embodiment of the present disclosure, and FIG. 8 shows a cross-sectional view taken along A-A in the display substrates shown in FIGS. 9 to 12. As shown in FIGS. 8 and 9, the orthographic projection of the second via hole K2 on the base 11 is within a range of the orthographic projection of the third via hole K3 on the base 11. A boundary on a side of the second via hole K2 close to the gate 163 may be a fourth boundary b4, a boundary on a side of the third via hole K3away from the gate 163 may be a third boundary b3, and a boundary on a side of the second via hole K2 away from the gate 163 may be a fifth boundary b5. A distance between the second boundary b2 and the fourth boundary b4 is larger than a distance between the third boundary b3 and the fifth boundary b5. That is, in an extension direction of the active layer 141, the second via hole K2 is not located at a center of the third via hole K3, and the second via hole K2 is closer to the third boundary b3 of the third via hole K3 in the third via hole K3; in other words, a distance between the second via hole K2 and the second boundary b2 is larger than a distance between the second via hole K2 and the third boundary b3.

In an exemplary embodiment, as shown in FIGS. 8 to 12, the first metal layer 16 may further include a gate line 164 extending in a first direction X (horizontal direction), and the gate 163 is connected to the gate line 164. The data line 121 extends in a second direction Y (vertical direction), and the first direction X intersects with the second direction Y, for example, the first direction X and the second direction Y may be perpendicular to each other. In the display substrate, the number of gate lines 164 may be a plurality, the number of data lines 121 may be a plurality, and the plurality of gate lines 164 and the plurality of data lines 121 intersect with each other to define sub-pixel regions.

Two adjacent data lines, 121a and 121b, are shown in FIGS. 9 to 12, and one sub-pixel region is between the data lines 121a and 121b. In a liquid crystal display panel, the third via hole K3 will cause light leakage. In order to avoid light leakage at the third via hole K3, the third via hole K3 usually needs to be blocked by a black matrix. Therefore, a position of the third via hole K3 will affect a size of the black matrix, thus affecting the aperture ratio. In a case where the aperture ratio is high, for example, the aperture ratio is greater than 70%, the position of the third via hole K3 cannot be arbitrarily changed, in order to prevent the third via hole K3 from affecting the aperture ratio. For example, by providing the distance between the second boundary b2 and the fourth boundary b4 to be greater than the distance between the third boundary b3 and the fifth boundary b5, compared to the embodiment of FIG. 4, the distance between the orthographic projection of the second via hole K2 on the base 11 and the first boundary b1 can be increased, so that the second via hole K2 is farther away from the first conductive region 141b, thereby avoiding the etching process from affecting the first conductive region 141b and ensuring the performance of the thin film transistor.

In a case where the distance between the second boundary b2 and the fourth boundary b4 is larger than the distance between the third boundary b3 and the fifth boundary b5, since a distance between the second via hole K2 and a right side boundary (third boundary b3) of the third via hole K3 is relatively small, the material of the planarization layer 18 is etched when the second via hole K2 is formed by the etching process. Therefore, the etching process used to form the second via hole K2 requires not only to etch the material of the insulating layer (that is, the material of the third insulating layer 19 and the material of the second insulating layer 17) but also etch the material of the planarization layer 18, and therefore, it is necessary to select an appropriate etching process so that the second via hole K2 can be formed by one etching process. When the second via hole K2 is etched, the first electrode 161 or the auxiliary barrier layer 142 located under the second via hole K2 may serve as an etching barrier, to avoid etching the first insulating layer 15 by the etching process.

In an exemplary embodiment, in an embodiment shown in FIG. 12, when the active layer 141 is conducted, a portion of the etching barrier layer located outside the first electrode 161 (that is, a portion of the etching barrier layer located between a lower boundary of the first electrode 161 and the gate line 164 in FIG. 12) is also conducted, and the etching barrier layer is located outside the first conductive region 141b, so that the damage of the etching barrier layer in the etching process does not affect the performance of the thin film transistor.

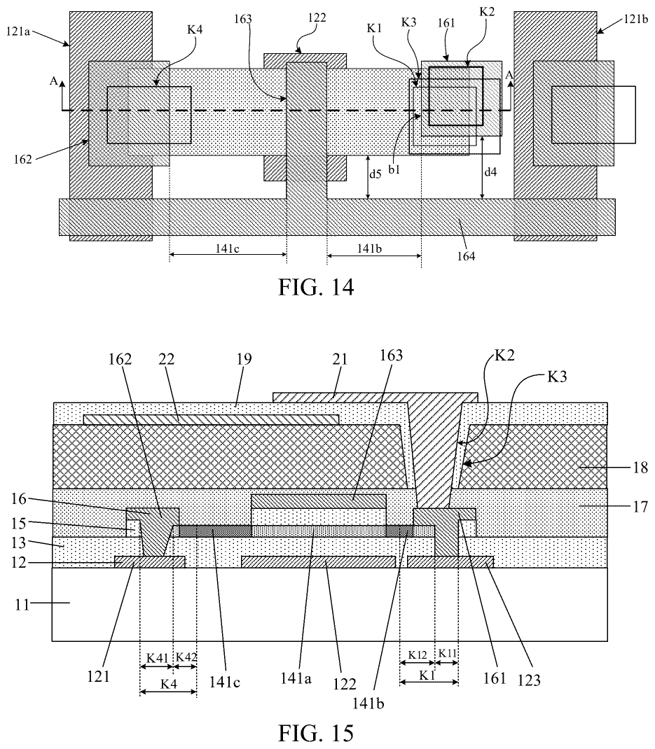

FIG. 13 shows a schematic cross-sectional view of a display substrate according to another embodiment of the present disclosure, FIG. 14 shows a schematic planar view of a part of a display substrate according to another embodiment of the present disclosure, and FIG. 13 shows a schematic cross-sectional view taken along A-A in the display substrate shown in FIG. 14.

In an embodiment of the present disclosure, there is a first overlapping region between the orthographic projection of the second via hole K2 on the base 11 and the orthographic projection of the third via hole K3 on the base 11, and a ratio of an area of the first overlapping region to an area of the orthographic projection of the third via hole K3 on the base 11 may range from 0.1 to 0.8. A ratio of the area of the first overlapping region to an area of the orthographic projection of the second via hole K2 on the base 11 may range from 0.5 to 1.

In an exemplary embodiment, when the orthographic projection of the second via hole K2 on the base 11 is located within the orthographic projection of the third via hole K3 on the base 11, the ratio of the area of the first overlapping region to the area of the orthographic projection of the second via hole K2 on the base 11 is 1.

In an exemplary embodiment, by providing the ratio of the area of the first overlapping region to the area of the orthographic projection of the third via hole K3 on the base 11 to be 0.1 to 0.8, the area of the third via hole K3 can be better controlled on the basis of satisfying a contact area between the first conductive electrode 21 and the first electrode 161, so that the area of the third via hole K3 can be better controlled, to avoid affecting the aperture ratio of the display product due to the too large area of the third via hole.

In an exemplary embodiment, by providing the ratio of the area of the first overlapping region to the area of the orthographic projection of the second via hole K2 on the base 11 to be 0.5 to 1, an etching amount of the material of the planarization layer 18 in the etching process of the second via hole K2 can be minimized, and the etching efficiency can be improved.

In some embodiments, as shown in FIG. 10, the first metal layer 16 further includes a gate line 164 and a second electrode 162, and the first electrode 161 and the second electrode 162 are located on two sides of the gate 163, respectively. The first insulating layer 15 is further provided with a fourth via hole K4, and the second electrode 162 is connected to the active layer 141 and the data line 121, respectively, through the fourth via hole K4. The first electrode 161 is provided with a first notch, and the first notch is located at a position of the first electrode 161 adjacent to the data line 121 and the gate line 164.

As shown in FIG. 10, the gate line 164 extends in the first direction X (horizontal direction), the data line 121 extends in the second direction Y (vertical direction), and the gate line 164 intersects with the data line 121. For example, the position of the first electrode 161 close to the data line 121 and the gate line 164 may be a position of the first electrode 161 close to an intersection position of the gate line 164 and the data line 121, for example, in FIG. 10, the intersection position of the gate line 164 and the data line 121 is a region C, and a lower right corner B of the first electrode 161 is close to the region C, so the position of the first electrode 161 adjacent to the data line 121 and the gate line 164 may be a position of the lower right corner B of the first electrode 161. A notch may be disposed at the lower right corner B to remove a portion of the first electrode 161, so that a region of the first electrode 161 from which the material is removed forms the first notch.

In an exemplary embodiment, when the aperture ratio of the display substrate is relatively large, for example, the aperture ratio is greater than 70%, a distance between the thin film transistor and the gate line 164 is relatively small, so that a distance between the first electrode 161 and the gate line 164 is relatively small. In this case, if the first electrode 161 is also disposed as a regular rectangular, the first electrode 161 may cause a short-circuit risk due to being relatively close to the gate line 164 and the data line 121. In order to avoid causing the short-circuit risk, a distance between the first electrode 161 and the region C can be increased by disposing the first notch, thereby reducing the short-circuit risk.

As shown in FIG. 10, the first notch includes a sixth boundary b6 and a seventh boundary b7, wherein the sixth boundary b6 is parallel to the gate line 164, and a distance d2 between the sixth boundary b6 and the gate line 164 is greater than or equal to 2.5 μm, and the distance d2 may be 4 μm, for example. The seventh boundary b7 is parallel to the data line 121, and a distance d3 between the seventh boundary b7 and the data line 121 is 2.5 μm or more, and the distance d2 may be 4 μm, for example. Such disposing mode can ensure that the distance between the lower right portion of the first electrode and the region C is far enough, thereby avoiding the short-circuit risk.

In some embodiments, when the aperture ratio of the display substrate is very large, for example, the aperture ratio is greater than or equal to 80%, as shown in FIGS. 11 to 14, the boundary of the first electrode 161 close to the gate line 164 (for example, the lower boundary of the first electrode 161 in the figure) is parallel to the gate line 164, and the boundary of the active layer 141 close to the gate line 164 is parallel to the gate line 164. A distance d4 between the lower boundary of the first electrode 161 and the gate line 164 is greater than a distance d5 between the lower boundary of the active layer 141 and the gate line 164, the distance d4 between the first electrode 161 and the gate line 164 is greater than or equal to 2.5 μm, and exemplarily, the distance d4 may be 4 μm. An orthographic projection of a boundary on a side of the third via hole K3 close to the gate line 164 on the base 11 is located between the orthographic projection of the first electrode 161 on the base 11 and the orthographic projection of the gate line 164 on the base 11.

It can be understood that, for a liquid crystal display product, the light leakage occurs at the position of the third via hole K3, and in order to avoid an influence of the light leakage of the third via hole K3 on the display effect, the distance between the third via hole K3 and the gate line 164 should be as small as possible, so that the black matrix can block the light leakage at the position of the third via hole K3, thereby improving the display effect.

When the aperture ratio of the display substrate is large, for example, the aperture ratio is 70% or more, the distance d4 between the first electrode 161 and the gate line 164 is 2.5 μm or more in order to avoid interference between adjacent metal traces, and thus a signal interference between the first electrode 161 and the gate line 164 can be avoided.

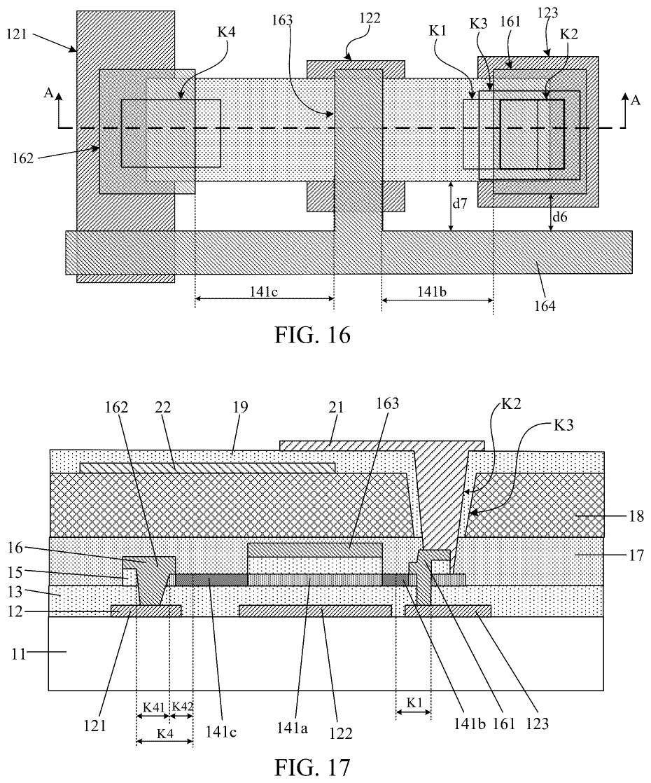

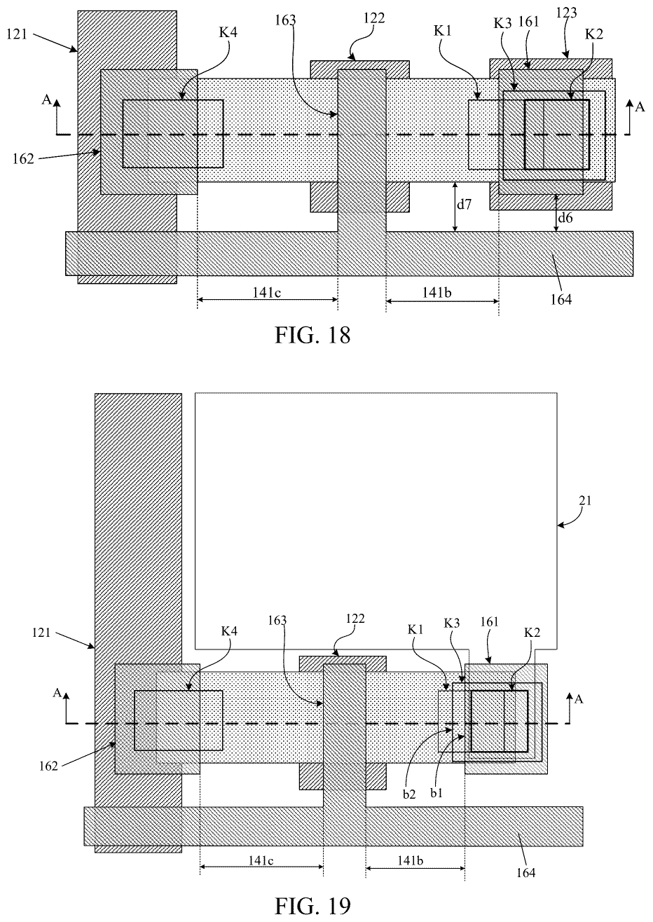

Compared to embodiments shown in FIGS. 16 and 18, the area of the first electrode 161 in the embodiments shown in FIGS. 11 to 14 is smaller, and the distance d4 between the lower boundary of the first electrode 161 and the gate line 164 is larger than the distance d6 between the lower boundary of the first electrode 161 and the gate line 164 in FIGS. 16 and 18. In an exemplary embodiment, the distance d5 between the active layer 141 and the gate line 164 in FIGS. 11 to 14 may be equal to the distance d7 between the active layer 141 and the gate line 164 in FIGS. 16 and 18.

In FIGS. 11 to 14, in order to avoid an influence of the third via hole K3 on the display effect, the distance between the third via hole K3 and the gate line 164 is as small as possible, and therefore, the lower boundary of the third via hole K3 is located between the first electrode 161 and the gate line 164. Then, the distance between the second via hole K2 and the lower boundary of the first electrode 161 is smaller than that in the embodiment of FIGS. 4 and 6, which may result in an overlapping region between the second via hole K2 and the active layer 141, and cause a contact connection between the first conductive electrode 21 and the active layer 141. In order to avoid the contact connection between the first conductive electrode 21 and the active layer 141, a second notch may be disposed on the active layer 141, and the second notch may be located at a position in the active layer 141 adjacent to the data line 121 and the gate line 164. That is, the second notch is located at a corner of the active layer 141 close to the data line 121 and the gate line 164, and in FIG. 11, the second notch is located at the lower right corner D of the active layer 141. A notch may be disposed at the position of the lower right corner D to remove a portion of the active layer 141, so that a region from which the material of the active layer 141 is removed forms the second notch.

As shown in FIG. 11, the second notch includes an eighth boundary b8 parallel to the gate line 164, and an orthographic projection of the eighth boundary b8 on the base 11 is located at an inner side of the orthographic projection of the first electrode 161 on the base 11. With such structure, after the first conductive electrode 21 is formed, the first conductive electrode 21 is not connected with the active layer 141 in a lapping mode.

A distance between the eighth boundary b8 and the lower boundary of the first electrode 161 may be provided as necessary, and a distance between the ninth boundary of the second notch and a right boundary of the active layer 141 may be provided as necessary, as long as it is ensured that the first conductive electrode 21 is not connected with the active layer 141 in a lapping mode.

In FIG. 12, a second notch may also be disposed to avoid lapping connection between the first conductive electrode 21 and the active layer 141. The boundary of the second notch in FIG. 12 may adopt a boundary E.

In one embodiment, as shown in FIG. 12, the boundary on the side of the third via hole K3 close to the gate line 164 is located between the orthographic projection of the first electrode 161 on the base 11 and the orthographic projection of the gate line 164 on the base 11, and the orthographic projection of the second via hole K2 on the base 11 is located within the orthographic projection of the third via hole K3 on the base 11.

In the present disclosure, as shown in FIG. 10, the second metal layer 12 includes the data line 121 and the shield portion 122, the first metal layer 16 further includes the second electrode 162, the first electrode 161 and the second electrode 162 are respectively located on two sides of the gate 163, the first insulating layer 15 is further provided with the fourth via hole K4, the second electrode 162 is respectively connected to the active layer 141 and the data line 121, and the orthographic projection of the gate 163 on the base 11 is located within an orthographic projection of the shield portion 122 on the base 11.

FIG. 15 shows a schematic cross-sectional view of a display substrate according to another embodiment of the present disclosure, FIG. 16 shows a schematic planar view of a part of a display substrate according to another embodiment of the present disclosure, and FIG. 15 shows a schematic cross-sectional view taken along A-A in the display substrate shown in FIG. 16; FIG. 17 shows a schematic cross-sectional view of a display substrate according to another embodiment of the present disclosure, FIG. 18 shows a schematic planar view of a part of a display substrate according to another embodiment of the present disclosure, and FIG. 17 shows a schematic cross-sectional view taken along A-A in the display substrate shown in FIG. 18. In some embodiments, as shown in FIGS. 6 and 18, the second boundary b2 may be located on the side of the first boundary b1 away from the gate 163. The orthographic projection of the second via hole K2 on the base 11 is located within the orthographic projection of the third via hole K3 on the base 11, so that the second via hole K2 is located on the side of the second boundary b2 away from the gate 163, that is, the second boundary b2 is located on a right side of the first boundary b1, and the second via hole K2 is located on a right side of the second boundary b2, so that compared to the embodiment shown in FIG. 4, the second via hole K2 is farther away from the first conductive region 141b, thereby avoiding the etching process from affecting the first conductive region 141b and ensuring the performance of the thin film transistor.

When the embodiment shown in FIG. 4 is adopted, it is needed to ensure a positional accuracy of the second via hole K2, and avoid etching the first conductive region 141b by the etching process of the second via hole K2 due to an alignment deviation of the second via hole K2. In the embodiment shown in FIG. 6, a risk that the first conductive region 141b is etched due to the alignment deviation of the second via hole K2 can be reduced, and the device performance of the thin film transistor can be further ensured.

In the embodiment shown in FIG. 6 or FIG. 18, the etching process of the second via hole K2 is avoided from affecting the first conductive region 141b by disposing the second boundary b2 on a side of the first boundary b1 away from the gate 163, so that the orthographic projection of the second via hole K2 on the base 11 can be disposed centrally within the orthographic projection of the third via hole K3 on the base 11, and the etching process of the second via hole K2 can be avoided from etching the material of the planarization layer 18.

In some embodiments, as shown in FIGS. 15 to 18, the second metal layer 12 includes an adapter portion 123, and the first electrode 161 is also connected to the adapter portion 123 through the first via hole K1. The first via hole K1 includes a first sub-hole and a second sub-hole. The first sub-hole penetrates the first insulating layer 15 and the buffer layer 13 to expose the adapter portion 123, and the second sub-hole penetrates the first insulating layer 15 to expose the active layer 141. The first electrode 161 is connected to the active layer 141 through the second sub-hole, and the first electrode 161 is connected to the adapter portion 123 through the first sub-hole. It has been proved by experiments that the connection resistance between the first electrode 161 and the active layer 141 can be reduced by adopting the embodiments shown in FIGS. 15 to 18.

In the liquid crystal display product, the first conductive electrode 21 may be a pixel electrode. The material of the first conductive electrode 21 may be a transparent conductive material such as indium tin oxide (ITO), indium zinc oxide (IZO), or the like. In an Organic Light-Emitting Diode (OLED) display panel, the first conductive electrode 21 may be understood as an anode of the OLED, and the material of the first conductive electrode 21 may include at least one of a metal, such as silver (Ag), aluminum (Al), titanium (Ti), and copper (Cu), and a metal alloy. The material of the second conductive electrode 22 may be the same as the material of the first conductive electrode 21.

In one embodiment, as shown in FIG. 3, the display substrate may further include a second conductive electrode 22, which may be located between the planarization layer 18 and the third insulating layer 19. Exemplarily, the first conductive electrode 21 may be a pixel electrode, and the second conductive electrode 22 may be a common electrode. The material of the second conductive electrode 22 may be the transparent conductive material.

FIG. 19 shows a schematic planar view of a display substrate according to another embodiment of the present disclosure, and FIG. 3 shows a schematic cross-sectional view taken along line A-A of FIG. 19. Hereinafter, the technical solutions of the embodiments of the present disclosure will be further explained by a manufacturing process of the display panel shown in FIGS. 3 and 19. It may be understood that for “patterning” mentioned in the present disclosure, when a patterned material is an inorganic material or metal, the “patterning” includes a process such as photoresist coating, mask exposure, development, etching, and photoresist stripping, when the patterned material is an organic material, the “patterning” includes a process such as mask exposure and development, and evaporation, deposition, coating, and coating, etc., mentioned in the present disclosure are all mature preparation processes in the related art.

First mask process: the second metal layer 12 is formed on a side of the base 11, and the second metal layer 12 includes the data line 121 and the shield portion 122; the buffer layer 13 is deposited on a side of the second metal layer 12 away from the base 11, as shown in FIGS. 3 and 19.

Second mask process: the active layer 141 is formed on a side of the buffer layer 13 away from the base 11, and a material of the active layer 141 may include a semiconductor oxide, for example, a semiconductor oxide such as indium gallium zinc oxide material (a-IGZO), zinc oxynitride (ZnON), or indium zinc tin oxide (IZTO) may be used as the material of the active layer 141.

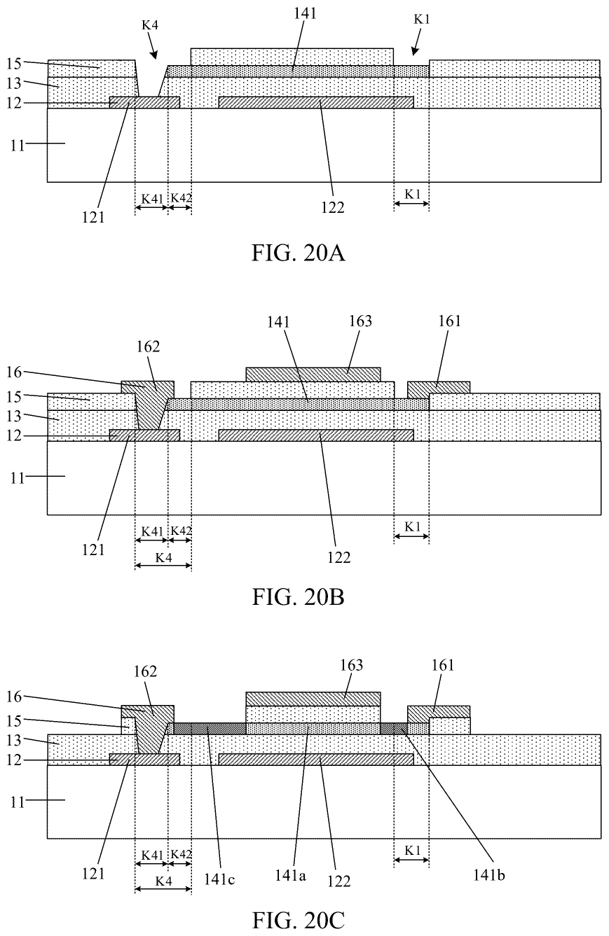

Third mask process: the first insulating layer 15 is formed on a side of the active layer 141 away from the base 11, the first insulating layer 15 is provided with the first via hole K1 and the fourth via hole K4, the fourth via hole K4 may include the third sub-hole K41 and the fourth sub-hole K42, the third sub-hole K41 penetrates the first insulating layer 15 and the buffer layer 13 and exposes a portion of the surface of the data line 121, and the fourth sub-hole K42 penetrates the first insulating layer 15 and exposes a portion of the surface of the active layer 141, as shown in FIG. 20A, which shows a schematic cross-sectional view of the display substrate after the first insulation layer is formed therein according to an embodiment of the present disclosure.

Fourth mask process: a first metal layer 16 is formed on a side of the first insulating layer 15 away from the base 11, the first metal layer 16 includes the gate 163, and the first electrode 161 and the second electrode 162 located on two sides of the gate 163, the first electrode 161 is connected with a portion of the exposed surface of the active layer 141 in a lapping mode through the first via hole K1, the second electrode 162 is connected to the data line 121 through the third sub-hole K41, and the second electrode 162 is connected with a portion of the exposed surface of the active layer 141 in a lapping mode through the fourth sub-hole K42, as shown in FIG. 20B, which shows a schematic cross-sectional view of the display substrate after the first metal layer is formed therein according to an embodiment of the present disclosure.

The first insulating layer 15 is etched with the first metal layer 16 as a mask to remove the material of the first insulating layer 15 located outside the first metal layer 16; the active layer 141 is conductive, the active layer 141 located outside the first metal layer 16 is conductive, the first conductive region 141b is formed between the gate 163 and the first electrode 161, and the second conductive region 141c is formed between the gate 163 and the second electrode 162, as shown in FIG. 20C, which shows a schematic cross-sectional view of the display substrate after the active layer is conducted therein according to an embodiment of the present disclosure.

Fifth mask process: the second insulating layer 17 is deposited on a side of the first metal layer 16 away from the base 11; a resin material is coated on a side of the second insulating layer 17 away from the base 11 to form the planarization layer 18, and the planarization layer 18 is patterned and a third via hole K3 penetrating the planarization layer 18 is formed, as shown in FIGS. 3 and 4. Exemplarily, a thickness of the second insulating layer 17 may be 0.1 μm to 0.2 μm. A thickness of the planarization layer may be 1 μm to 2 μm.

Sixth mask process: the second conductive electrode 22 is formed on a side of the planarization layer 18 away from the base 11, as shown in FIG. 3.

Seventh mask process: the third insulating layer 19 is deposited on a side of the second conductive electrode 22 away from the base 11, the third insulating layer 19 and the first insulating layer 15 are patterned and the second via hole K2 is formed, the second via hole K2 penetrates the third insulating layer 19 and the first insulating layer 15 to expose the surface of the first electrode 161, and the orthographic projection of the second via hole K2 on the base 11 is located within the orthographic projection of the third via hole K3 on the base 11, as shown in FIGS. 3 and 19. Exemplarily, a thickness of the third insulating layer may be 0.2 μm to 0.9 μm.

Eighth mask process: the first conductive electrode 21 is formed on a side of the third insulating layer 19 away from the base 11, and the first conductive electrode 21 is connected to the first electrode 161 through the second via hole K2, as shown in FIGS. 3 and 19. Herein, FIG. 19 shows a frame of the first conductive electrode 21, and a shape of the first conductive electrode 21 may be provided as necessary, for example, the first conductive electrode 21 may include a plurality of strip-shaped electrodes, or the first conductive electrode 21 may be a planar electrode. An electrical field for driving the liquid crystals may be formed between the first conductive electrode 21 and the second conductive electrode 22.

Through experiments, it has been proved that in the display substrate of the embodiment of the present disclosure, the connection resistance between the first conductive electrode 21 and the first electrode 161 is less than 3000 ohm, which can meet the performance requirements of the display substrate.

In an exemplary embodiment, the first insulating layer 15, the second insulating layer 17, the third insulating layer 19, and the buffer layer 13 may be made of any one or more of Silicon Oxide (SiOx), Silicon Nitride (SiNx), and Silicon Oxynitride (SiON), and may be a single layer, a multi-layer, or a composite layer. The first insulating layer 15 may be called a gate insulating layer (GI), the second insulating layer 17 may be called a first passivation layer (PVX1), and the third insulating layer 19 may be called a second passivation layer (PVX2). The first metal layer 16 and the second metal layer 12 may be made of a metal material, such as any one or more of silver (Ag), copper (Cu), aluminum (Al), titanium (Ti) and molybdenum (Mo), or an alloy material of the aforementioned metals, such as an aluminum neodymium alloy (AlNd) or a molybdenum niobium alloy (MoNb), and they may be of a single-layered structure or a multi-layered composite structure, such as Ti/Al/Ti. The pixel definition layer may be made of polyimide, acrylic, polyethylene terephthalate, or the like.

The display substrate of the embodiment of the present disclosure may be applied to a Liquid Crystal Display (LCD) display product, and the display substrate may be served as an array display substrate of an LCD panel.

An embodiment of the present disclosure further provides a display panel, including the display substrate according to any embodiment of the present disclosure. The display panel may be an LCD display panel or an OLED display panel.

When the display panel is the LCD display panel, the display panel may further include a color film display substrate, and the color film display substrate may be disposed in an alignment with the display substrate of the embodiment of the present disclosure.

Embodiments of the present disclosure further provide a display device, and the display device may include the display substrate according to any embodiment of the present disclosure, or the display device may include the display panel according to any embodiment of the present disclosure. The display device may be an LCD display device, an OLED display device, or a Quantum Dot Light Emitting Diode (QLED) display device.

The display device may be any product or component with a display function, such as a mobile phone, a tablet computer, a television, a display, a laptop computer, a digital photo frame, and a navigator.

According to a technical solution of an embodiment of the present disclosure, the orthographic projection of the second via hole on the base is located on a side of the first boundary away from the gate, and the first boundary is a partition boundary between the first sub-portion and the second sub-portion, so that the first conductive region is not affected when the second via hole is formed by the etching process, and the stability of the characteristic of the thin film transistor is ensured. The orthographic projection of the second via hole on the base is located on the side of the first boundary away from the gate, and the orthographic projection of the second via hole on the base is located on the region outside the first conductive region between the first electrode and the gate, so that the first conductive region of the active layer is not exposed by the second via hole, and the first conductive region is covered by the second insulating layer, thereby the first conductive region is not anti-conducted in processes after the first conductive electrode is formed, the connection resistance between the first conductive electrode and the active layer is reduced, and the product power consumption is reduced. Therefore, in the display substrate of the embodiment of the present disclosure, the connection resistance between the first conductive electrode and the active layer is reduced, the charging current of the product is improved, and the performance of the display substrate is improved.

In the description of the present specification, it should be understood that, orientation or position relationships indicated by terms “center”, “longitudinal”, “transverse”, “length”, “width”, “thickness”, “upper”, “lower”, “front”, “back”, “left”, “right”, “vertical”, “horizontal”, “top”, “bottom”, “inside”, “outside”, “clockwise”, “counterclockwise”, “axial”, “radial”, “circumferential” and the like are based on the orientation or position relationships shown in the drawings, and are only for the convenience of description of the present disclosure and simplification of the description, but are not intended to indicate or imply that the mentioned device or element must have a specific orientation, or be constructed and operated in a particular orientation, and therefore they should not be construed as limitations on the present disclosure.

In addition, terms “first” and “second” are used for descriptive purposes only and cannot be interpreted as indicating or implying relative importance or implicitly indicating a quantity of technical features indicated. Therefore, features defined by “first” or “second” may explicitly or implicitly include one or more such features. In the description of the present disclosure, a meaning of “a plurality of” is two or more than two, unless defined otherwise explicitly.

In the present disclosure, unless otherwise clearly specified and defined, terms “install”, “connect”, “couple”, “fix” and other terms should be broadly understood. For example, it may be a fixed connection, a detachable connection, or an integrated connection; or it may be a mechanical connection, an electrical connection, or a communication; or it may be a direct connection, an indirect connection through an intermediary, or an internal communication between two elements or an interaction between two elements. Those of ordinary skills in the art may understand meanings of the aforementioned terms in the present disclosure according to situations.

In the present disclosure, a first feature being “above” or “below” a second feature may include direct contact of the first feature and the second feature, or may include indirect contact of the first feature and the second feature through additional feature(s) between them, unless otherwise expressly specified and defined. Moreover, the first feature being “over”, “upper” and “on” the second feature may mean that the first feature is directly above or obliquely above the second feature, or simply mean that a level of the first feature is greater than that of the second feature. The first feature being “beneath”, “under” and “below” the second feature includes the first feature being directly above and obliquely above the second feature, or simply means that a level of the first feature is lower than that of the second feature.

Many different implementations or examples disclosed above are provided for implementing different structures of the present disclosure. In order to simplify the present disclosure, components and arrangements of specific examples are described above. Of course, they are examples only and are not intended to limit the present disclosure. In addition, in the present disclosure, reference numbers and/or reference letters may be repeated in different examples. Such repetition is for a purpose of simplification and clarity, and itself does not indicate a relationship between various implementations and/or arrangements discussed.

The above is only implementations of the present disclosure, but the protection scope of the present disclosure is not limited to this. Any person skilled with this technical field may easily conceive various variations or substitutions within the technical scope disclosed in the present disclosure, which should be covered within the protection scope of the present disclosure. Therefore, the protection scope of the present disclosure shall be subject to the protection scope of the claims.

1. A display substrate, comprising:
a base;
an active layer located on a side of the base;
a first insulating layer located on a side of the active layer away from the base, wherein the first insulating layer is provided with a first via hole that exposes a portion of a surface of the active layer;
a first metal layer located on a side of the first insulating layer away from the base, wherein the first metal layer comprises a gate and a first electrode, a portion of the active layer exposed through the first via hole comprises a first sub-portion and a second sub-portion, the first sub-portion is located on a side of the second sub-portion away from the gate, and the first electrode is connected with the first sub-portion in a lapping mode through the first via hole;
a second insulating layer located on a side of the first metal layer away from the base, wherein the second insulating layer is provided with a second via hole, an orthographic projection of the second via hole on the base is at least partially overlapped with an orthographic projection of the first electrode on the base, the orthographic projection of the second via hole on the base is located on a side of a first boundary away from the gate, and the first boundary is a partition boundary between the first sub-portion and the second sub-portion; and
a first conductive electrode located on a side of the second insulating layer away from the base, wherein the first conductive electrode is connected with the first electrode through the second via hole.

2. The display substrate according to claim 1, wherein the orthographic projection of the second via hole on the base is located in the orthographic projection of the first electrode on the base.

3. The display substrate according to claim 1, further comprising an auxiliary barrier layer disposed in a same layer as the active layer, wherein the orthographic projection of the second via hole on the base is partially overlapped with the orthographic projection portion of the first electrode on the base, and an orthographic projection of a portion of the second via hole outside the first electrode on the base is within an orthographic projection of the auxiliary barrier layer on the base.

4. The display substrate according to claim 1, further comprising a planarization layer disposed between the second insulating layer and the first conductive electrode, wherein the planarization layer is provided with a third via hole, the orthographic projection of the second via hole on the base is at least partially overlapped with an orthographic projection of the third via hole on the base, and the second via hole penetrates the planarization layer and the second insulating layer.

5. The display substrate according to claim 4, wherein a second boundary is located on a side of the first boundary close to the gate, and the second boundary is a boundary on a side of the third via hole close to the gate.

6. The display substrate according to claim 5, wherein the orthographic projection of the second via hole on the base is within a range of the orthographic projection of the third via hole on the base, and a distance between a boundary of the orthographic projection of the second via hole on the base and a boundary of the orthographic projection of the third via hole on the base is greater than or equal to 2 μm.

7. The display substrate according to claim 5, wherein the orthographic projection of the second via hole on the base is located within a range of the orthographic projection of the third via hole on the base, a distance between the second boundary and a fourth boundary is larger than a distance between a third boundary and a fifth boundary, the fourth boundary is a boundary on a side of the second via hole close to the gate, the third boundary is a boundary on a side of the third via hole away from the gate, and the fifth boundary is a boundary on a side of the second via hole away from the gate.

8. The display substrate according to claim 4, wherein a second boundary is located on a side of the first boundary away from the gate, the second boundary is a boundary on a side of the third via hole close to the gate, and the orthographic projection of the second via hole on the base is located on a side of the second boundary away from the gate.

9. The display substrate according to claim 4, wherein there is a first overlapping region between the orthographic projection of the second via hole on the base and the orthographic projection of the third via hole on the base, a ratio of an area of the first overlapping region to an area of the orthographic projection of the third via hole on the base ranges from 0.1 to 0.8, and a ratio of the area of the first overlapping region to an area of the orthographic projection of the second via hole on the base ranges from 0.5 to 1.

10. The display substrate according to claim 1, further comprising a second metal layer and a buffer layer between the base and the active layer, wherein the second metal layer is close to the base, the second metal layer comprises a data line, the first metal layer further comprises a gate line and a second electrode, the first electrode and the second electrode respectively located on two sides of the gate, the first insulating layer is further provided with a fourth via hole, the second electrode is connected to the active layer and the data line through the fourth via hole, the first electrode is provided with a first notch, and the first notch is located at a position of the first electrode adjacent to the data line and the gate line.

11. The display substrate according to claim 10, wherein the first notch comprises a sixth boundary and a seventh boundary, the sixth boundary is parallel to the gate line, a distance between the sixth boundary and the gate line is greater than or equal to 2.5 μm, the seventh boundary is parallel to the data line, and a distance between the seventh boundary and the data line is greater than or equal to 2.5 μm.

12. The display substrate according to claim 5, wherein the first metal layer further comprises a gate line, a boundary of the first electrode close to the gate line is parallel to the gate line, a boundary of the active layer close to the gate line is parallel to the gate line, a distance between the first electrode and the gate line is greater than a distance between the active layer and the gate line, a distance between the first electrode and the gate line is greater than or equal to 2.5 μm, and an orthographic projection of a boundary of the third via hole close to the gate line on the base is between the orthographic projection of the first electrode on the base and an orthographic projection of the gate line on the base.

13. The display substrate according to claim 12, wherein the active layer is provided with a second notch located at a position of the active layer adjacent to the gate line, the second notch comprises an eighth boundary, the eighth boundary is parallel to the gate line, and an orthographic projection of the eighth boundary on the base is located at an inner side of the orthographic projection of the first electrode on the base.

14. The display substrate according to claim 12, wherein the orthographic projection of the second via hole on the base is within the orthographic projection of the first electrode on the base, and the orthographic projection of the second via hole on the base is partially overlapped with the orthographic projection of the third via hole on the base.

15. The display substrate according to claim 12, wherein the boundary of the third via hole close to the gate line is located between the orthographic projection of the first electrode on the base and the orthographic projection of the gate line on the base, and the orthographic projection of the second via hole on the base is located within the orthographic projection of the third via hole on the base.

16. The display substrate according to claim 1, further comprising a second metal layer and a buffer layer between the base and the active layer, wherein the second metal layer is close to the base, the second metal layer comprises a data line and a shield portion, the first metal layer further comprises a second electrode, the first electrode and the second electrode is respectively located on two sides of the gate, the first insulating layer is further provided with a fourth via hole, the second electrode is connected to the active layer and the data line through the fourth via hole, and an orthographic projection of the gate on the base is located within an orthographic projection of the shield portion on the base.

17. The display substrate according to claim 1, further comprising a second metal layer and a buffer layer between the base and the active layer, wherein the second metal layer is close to the base, the second metal layer comprises an adapter portion, and the first electrode is further connected to the adapter portion through the first via hole.

18. A display panel, comprising the display substrate according to claim 1.

19. A display device, comprising the display substrate according to claim 1.

20. A display device, comprising the display panel according to claim 18.
